(19) United States
(12) Patent Application Publication
(10) Pub. No.: US 2006/0220727 A1
(43) Pub. Date: Oct. 5, 2006

(54) ELECTRONIC SWITCH AND OPERATIONAL METHOD FOR TRANSISTOR

(76) Inventor: Chih-Jen Yen, Hsinchu City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/160,740

(22) Filed: Jul. 7, 2005

(30) Foreign Application Priority Data
Mar. 30, 2005 (TW) 94109941

(51) Int. Cl. H03K 3/01

(52) U.S. Cl. 327/534

(57) ABSTRACT

An electronic switch and an operational method for transistor are provided. The electronic switch includes a switch transistor and a bulk switch. The switch transistor has at least a first terminal, a second terminal and a third terminal. According to the third terminal, the connecting status between the first and the second terminal is determined. The bulk switch is coupled to the bulk of the switch transistor for determining whether to connect the bulk to the first or the second terminal of the switch transistor according to at least one control signal.

### CROSS-REFERENCE TO RELATED APPLICATION

This application claims the priority benefit of Taiwan application serial no. 94109941, filed on Mar. 30, 2005. All disclosure of the Taiwan application is incorporated herein by reference.

### BACKGROUND OF THE INVENTION

1. Field of the Invention

The present invention relates to an electronic switch, and more particularly to an electronic switch for preventing the incorrect turn-on of PN-junction forward bias, and an operational method for transistor.

2. Description of the Related Art

Electronic circuits usually include many electronic switches. Most of the electronic switches are composed of MOS transistors. A connection between source and drain is determined by a control signal of gate. In such an electronic circuit, the bulk of the transistor is coupled to a fixed voltage.

The following is to describe the incorrect turn-on issue of PN-junction forward bias in a charge pump circuit. FIG. 1A is a drawing showing a conventional charge pump circuit. FIG. 1B is a drawing showing a timing diagram of control signals of electronic switches in the charge pump circuit of FIG. 1A. Referring to FIGS. 1A and 1B, the electronic switches 101, 103 and 104 are PMOS transistors. The electronic switch 102 is an NMOS transistor. Wherein, the bulk of each of the electronic switches 101-104 is coupled to its own source. During the charge period (CP), the control signals ph1 and ph2b are at high level and the control signal ph1b is at low level. As a result, the electronic switches 101 and 102 are turned on and the electronic switches 103 and 104 are turned off. The input voltage VIN and the ground voltage GND are respectively coupled to two terminals of the capacitor 105 for charging. The voltage difference between the nodes N1 and N2 is the input voltage VIN. During the pump period (PP), the control signals ph1 and ph2b are at low level and the control signal ph1b is at high level. Accordingly, the electronic switches 101 and 102 are turned off, and the electronic switches 103 and 104 are turned on. The voltage at the node N2 is raised from 0V to VIN, and the voltage at the node N1 is raised from VIN to 2VIN so as to charge the capacitor 106, and serve as the output voltage VOUT.

Ideally, the charge pump circuit in FIG. 1A can function normally. In practice, the electronic switches 101 and 104 would cause output voltage error due to the forward-bias turn-on of the PN junction. FIG. 1C is a cross-section view of the electronic switch 101 in FIG. 1A. Referring to FIGS. 1A and 1C, the gate G is at low level and a P channel is formed between the source S and the drain D during CP. Next in the PP, the gate G is at high level and the P channel disappears. As a result, the electronic switch 101 becomes cut off. As described above, the voltage at the node N1 is 2VIN, and the voltage of the bulk B, i.e., the N-well in FIG. 3, is VIN. Thus, the forward bias of PN junction between the drain D and the bulk B is turned on. In other words, the electronic switch 101 is mistakenly turned on, which causes the voltage of the node N1 to be clamped at a voltage slightly higher than VIN during PP. As a result, the voltage cannot be raised.

### SUMMARY OF THE INVENTION

Accordingly, the present invention is directed to an electronic switch for avoiding abnormal operation caused by the forward-bias turn-on of PN junction.

The present invention is also directed to an operational method for a transistor to prevent the abnormal operation of the transistor caused by the incorrect turn-on of the PN-junction forward bias.

According to the objects described above and other objects, the present invention provides an electronic switch comprising a switch transistor and a bulk switch. The switch transistor at least comprises a first terminal, a second terminal and a third terminal. The switch transistor determines a connection status between the first terminal and the second terminal according to the third terminal. The bulk switch is coupled to the bulk of the switch transistor for determining whether to connect the bulk of the switch transistor to the first terminal of the switch transistor or the second terminal of the switch transistor according to at least one control signal.

According to the electronic switch in an embodiment of the present invention, if the switch transistor is a PMOS transistor, the bulk of the switch transistor is coupled to one of the first terminal and the second terminal of the switch transistor that has a higher voltage according to the control signal. If the switch transistor is an NMOS transistor, the bulk of the switch transistor is coupled to one of the first terminal and the second terminal of the switch transistor that has a lower voltage according to the control signal.

According to the electronic switch in an embodiment of the present invention, the control signal comprises a first switch signal and a second switch signal. The bulk switch comprises a first transistor and a second transistor. A source of the first transistor is coupled to the first terminal of the switch transistor, a drain of the first transistor is coupled to the bulk of the switch transistor, and a gate of the first transistor receives the first switch signal. A source of the second transistor is coupled the second terminal of the switch transistor, a drain of the second transistor is coupled to the bulk of the switch transistor, and a gate of the second transistor receives the second switch signal.

Additionally, the present invention also provides an operational method for a transistor. The operational method is adapted to operate a switch transistor with at least a first terminal, a second terminal and a third terminal. Wherein, a connection status between the first terminal and the second terminal is determined according to the third terminal. The operational method for the switch transistor comprises determining whether to connect the bulk of the switch transistor to the first terminal of the switch transistor or the second terminal of the switch transistor according to at least one control signal.

According to the operational method for the transistor in an embodiment of the present invention, if the switch transistor is a PMOS transistor, the operational method for the switch transistor further comprises coupling the bulk of the switch transistor to one of the first terminal and the second terminal of the switch transistor that has a higher voltage according to the control signal.

According to the operational method for the transistor in an embodiment of the present invention, if the switch transistor is an NMOS transistor, the operational method for the switch transistor further comprises coupling the bulk of the switch transistor to one of the first terminal and the second terminal of the switch transistor that has a lower voltage according to the control signal.

According to the present invention, the bulk of the transistor is dynamically switched to either the first terminal or the second terminal according to the control signal. Thus, the coupling of the bulk is not fixed, and the body effect is avoided.

The above and other features of the present invention will be better understood from the following detailed description of the preferred embodiments of the invention that is provided in communication with the accompanying drawings.

### BRIEF DESCRIPTION OF THE DRAWINGS

FIG. 1A is a drawing showing a conventional charge pump circuit.

FIG. 1B is a drawing showing a timing diagram of control signals of electronic switches in the charge pump circuit in FIG. 1A.

FIG. 1C is a cross-section view of the electronic switch 101 in FIG. 1A.

FIG. 2 is a schematic drawing showing an electronic switch according to an embodiment of the present invention.

FIG. 3 is a schematic drawing showing an electronic switch according to another embodiment of the present invention.

FIG. 4 is a schematic drawing showing an electronic switch according to yet another embodiment of the present invention.

FIG. 5 is a schematic drawing showing a charge pump circuit according to an embodiment of the present invention.

### DESCRIPTION OF SOME EMBODIMENTS

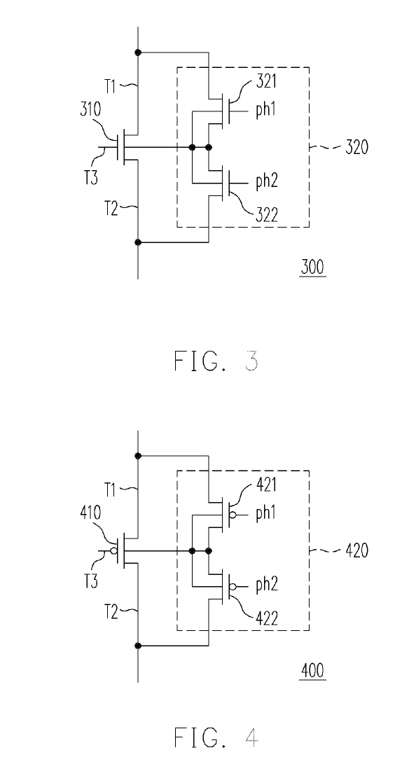

FIG. 2 is a schematic drawing showing an electronic switch according to an embodiment of the present invention. Referring to FIG. 2, the electronic switch 200 comprises the switch transistor 210 and the bulk switch 220. The switch transistor 210 at least comprises a first terminal T1, a second terminal T2 and a third terminal T3. The switch transistor 210 determines a connection status between the first terminal T1 and the second terminal T2 according to the third terminal T3. The bulk switch 220 is coupled to the bulk of the switch transistor 210. The bulk switch 220 determines whether to connect the bulk of the switch transistor 210 to the first terminal T1 of the switch transistor 210 or the second terminal T2 of the switch transistor 210 according to at least one control signal ph. In this embodiment, the switch transistor 210 is an NMOS transistor. When operating the electronic switch 200, the bulk of the switch transistor 210 is coupled to one of the first terminal T1 and the second terminal T2 of the switch transistor 210 that has a lower voltage according to the control signal ph. If the switch transistor 210 is a PMOS transistor, the bulk of the switch transistor 210 is coupled to one of the first terminal T1 and the second terminal T2 of the switch transistor 210 that has a higher voltage according to the control signal ph.

FIG. 3 is a schematic drawing showing an electronic switch according to another embodiment of the present invention. Referring to FIG. 3, the electronic switch 300 comprises the NMOS switch transistor 310 and the bulk switch 320. Wherein, the control signal ph comprises a first switch signal ph1 and a second switch signal ph2. The bulk switch 320 comprises a first transistor 321 and a second transistor 322. A source of the first transistor 321 is coupled to the first terminal T1 of the switch transistor 310, a drain of the first transistor 321 is coupled to the bulk of the switch transistor 310, and a gate of the first transistor 321 receives the first switch signal ph1. A source of the second transistor 322 is coupled the second terminal T2 of the switch transistor 310, a drain of the second transistor 322 is coupled to the bulk of the switch transistor 310, and a gate of the second transistor 322 receives the second switch signal ph2. In this embodiment, the bulks of the transistors 321 and 322 are coupled to the bulk of the switch transistor 310. When operating the electronic switch 300, the bulk switch 320 is controlled by the control signal, i.e., the first switch signal phi and the second switch signal ph2, so that the bulk of the switch transistor 310 is coupled to either the first terminal T1 or the second terminal T2, which has a lower voltage.

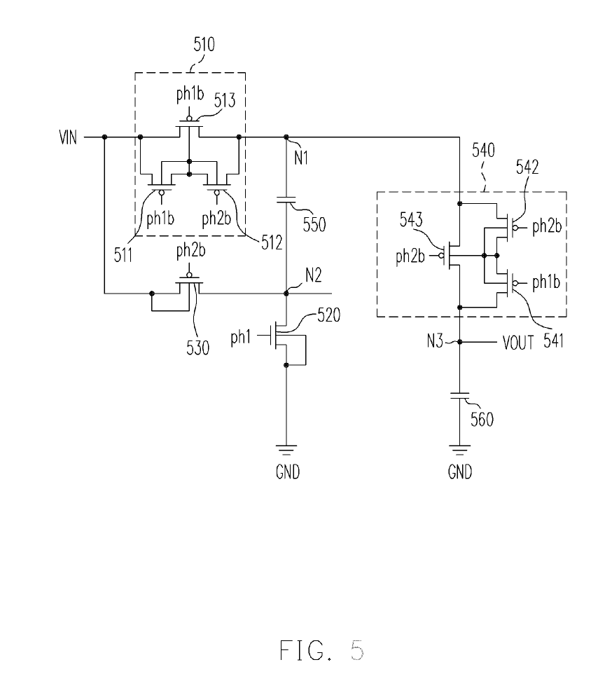

FIG. 4 is a schematic drawing showing an electronic switch according to yet another embodiment of the present invention. Referring to FIG. 4, the electronic switch 400 comprises the PMOS switch transistor 410 and the bulk switch 420. Wherein, the bulk switch 420 comprises a first transistor 421 and a second transistor 422. A source of the first transistor 421 is coupled to the first terminal T1 of the switch transistor 410, a drain of the first transistor 421 is coupled to the bulk of the switch transistor 410, and a gate of the first transistor 421 receives the first switch signal ph1. A source of the second transistor 422 is coupled the second terminal T2 of the switch transistor 410, a drain of the second transistor 422 is coupled to the bulk of the switch transistor 410, and a gate of the second transistor 422 receives the second switch signal ph2. In this embodiment, the bulks of the transistors 421 and 422 are coupled to the bulk of the switch transistor 410. When operating the electronic switch 400, the bulk switch 420 is controlled by the control signal, i.e., the first switch signal ph1 and the second switch signal ph2, so that the bulk of the switch transistor 410 is coupled to either the first terminal T1 or the second terminal T2, which has a higher voltage.

In order to clearly interpret the present invention, a charge pump circuit is cited as an example to explain the electronic switch in the present invention. One knows the ordinary skill in the art can apply the electronic switch of the present invention to any circuit. The present invention is not limited to this embodiment.

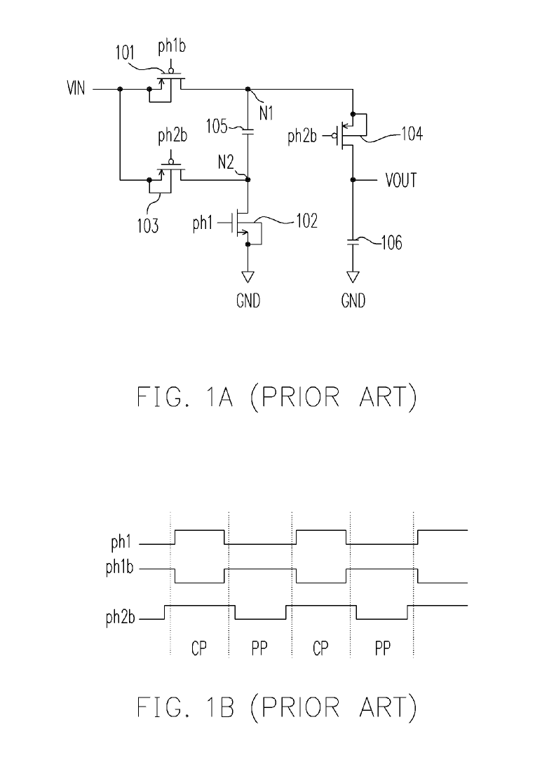

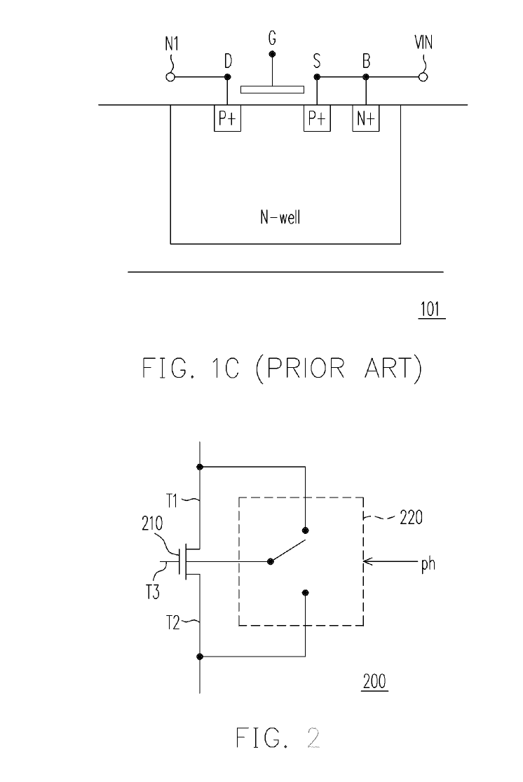

FIG. 5 is a schematic drawing showing a charge pump circuit according to an embodiment of the present invention. Referring to FIGS. 5 and 1B, the electronic switch 530 can be, for example, a PMOS transistor, and the electronic switch 520 can be, for example, an NMOS transistor. In addition, the electronic switches 510 and 540 are implemented by the electronic switch 400 in FIG. 4, for example.

During the charge period CP, the control signals ph1 and ph2b are at high level, and the control signal ph1b is at low level. Accordingly, the electronic switches 510 and 520 are turned on, and the electronic switches 530 and 540 are turned off. In addition, the transistors 541 and 542 are controlled by the control signals ph1b and ph2b so that the coupling of the bulk of the switch transistor 543 is switched from the node N1 to the node N3, which is at a higher level. The input voltage VIN and the ground voltage GND are then coupled to two terminals of the capacitor 550 and charge the capacitor 550. As a result, the voltage difference between the nodes N1 and N2 is the input voltage VIN.

During the pump period PP, the control signals ph1 and ph2b are at low level, and the control signal ph1b is at high level. Accordingly, the electronic switches 510 and 520 are turned off, and the electronic switches 530 and 540 are turned on. The voltage at the node N2 is raised from 0V to VIN. The voltage at the node N1 is raised from VIN to 2VIN. The capacitor 560 then is charged to serve as an output voltage VOUT. In other words, the voltage at the node N1 is larger than the input voltage VIN. The transistors 511 and 512 are controlled by the control signals ph1b and ph2b so that the coupling of the bulk of the switch transistor 513 is switched from the input voltage VIN to the node N1, which is at a higher level.

According to the present invention, the coupling of the bulk of the transistor is dynamically switched to either the first terminal or the second terminal according to the control signal. The coupling of the bulk is not fixed. Thus, the incorrect turn-on of the PN-junction forward bias is avoided.

Although the present invention has been described in terms of exemplary embodiments, it is not limited thereof. Rather, the appended claims should be constructed broadly to include other variants and embodiments of the invention which may be made by those skilled in the field of this art without departing from the scope and range of equivalents of the invention.

What is claimed is:

1. An electronic switch, comprising:
a switch transistor comprising at least a first terminal, a second terminal and a third terminal, for determining a connection status between the first terminal and the second terminal according to the third terminal; and
a bulk switch, coupled to the bulk of the switch transistor, for determining whether to connect the bulk of the switch transistor to the first terminal of the switch transistor or the second terminal of the switch transistor according to at least one control signal.

2. The electronic switch as claimed in claim 1 wherein the switch transistor is a PMOS transistor, and the bulk of the switch transistor is coupled to one of the first terminal and the second terminal of the switch transistor that has a higher voltage according to the control signal.

3. The electronic switch as claimed in claim 1 wherein the switch transistor is an NMOS transistor, and the bulk of the switch transistor is coupled to one of the first terminal and the second terminal of the switch transistor that has a lower voltage according to the control signal.

4. The electronic switch as claimed in claim 1 wherein the control signal comprises a first switch signal and a second switch signal, the bulk switch comprising:
a first transistor, a source of which being coupled to the first terminal of the switch transistor, a drain of which being coupled to the bulk of the switch transistor, a gate of which receiving the first switch signal; and
a second transistor, a source of which being coupled to the second terminal of the switch transistor, a drain of which being coupled to the bulk of the switch transistor, a gate of which receiving the second switch signal.

5. The electronic switch as claimed in claim 4 wherein the bulk of the first transistor and the bulk of the second transistor are coupled to the bulk of the switch transistor.

6. The electronic switch as claimed in claim 4 wherein the switch transistor, the first transistor and the second transistor are NMOS transistors.

7. The electronic switch as claimed in claim 4 wherein the switch transistor, the first transistor and the second transistor are PMOS transistors.

8. An operational method for a switch transistor with at least a first terminal, a second terminal and a third terminal, wherein a connection status between the first terminal and the second terminal is determined according to the third terminal, the operational method for the switch transistor comprising:
determining whether to connect the bulk of the switch transistor to the first terminal of the switch transistor or the second terminal of the switch transistor according to at least one control signal.

9. The operational method for a switch transistor as claimed in claim 8 wherein the switch transistor is a PMOS transistor, and the operational method for the switch transistor further comprises:
coupling the bulk of the switch transistor to one of the first terminal and the second terminal of the switch transistor, which has a higher voltage.

10. The operational method for a switch transistor as claimed in claim 8 wherein the switch transistor is an NMOS transistor, and the operational method for the switch transistor further comprises:
coupling the bulk of the switch transistor to one of the first terminal and the second terminal of the switch transistor, which has a lower voltage.
